(19) United States
(12) Patent Application Publication
(10) Pub. No.: US 2025/0031495 A1
(43) Pub. Date: Jan. 23, 2025

(54) RADIATION-EMITTING COMPONENT AND METHOD FOR PRODUCING A RADIATION-EMITTING COMPONENT

(71) Applicant: ams-OSRAM International GmbH, Regensburg (DE)

(72) Inventors: Florian PESKOLLER, Ingolstadt (DE); Gertrud KRAEUTER, Regensburg (DE); Angela EBERHARDT, Augsburg (DE); Moritz LAUBSCHER, Göllheim (DE)

(21) Appl. No.: 18/712,735

(22) PCT Filed: Nov. 24, 2022
(86) PCT No.: PCT/EP2022/083090

§ 371 Date: May 23, 2024

(30) Foreign Application Priority Data
Nov. 26, 2021 (DE) 102021131112.8

(51) Int. Cl. H01L 33/50; H01L 25/075; H01L 33/62; H01S 5/00

(52) U.S. Cl. CPC H01L 33/505; H01L 25/0753; H01L 33/502; H01L 33/62; H01S 5/0078; H01L 2933/0041

(57) ABSTRACT

A radiation-emitting component includes a semiconductor chip which, in operation, emits electromagnetic radiation of a first wavelength range from a radiation exit surface, and a conversion element on a cover surface of the semiconductor chip comprising the radiation exit surface. The conversion element contains a matrix material and phosphor particles embedded therein which convert electromagnetic radiation of the first wavelength range into electromagnetic radiation of a second wavelength range. The conversion element has a bearing surface which is equal to or smaller than the cover surface of the semiconductor chip, and the bearing surface is completely in direct contact with the cover surface of the semiconductor chip. A method for producing a radiation-emitting component is further disclosed.

### RELATED APPLICATION(S)

This application is a US National Stage Application of International Application PCT/EP2022/083090, filed on 24 Nov. 2022, and claims priority under 35 U.S.C. § 119 (a) and 35 U.S.C. § 365 (b) from German Patent Application DE 10 2021 131 112.8, filed on 26 Nov. 2021, the contents of which are incorporated herein by reference in their entirety.

### FIELD

The present disclosure relates to radiation-emitting components and a methods for producing a radiation-emitting components.

### SUMMARY

At least one embodiment of the present disclosure relates to a radiation-emitting component with improved properties. At least one further embodiment relates to a method for producing a radiation-emitting component with improved properties.

According to various embodiments of the present disclosure, a radiation-emitting component is disclosed. The radiation-emitting component has a semiconductor chip which, during operation, emits electromagnetic radiation of a first wavelength range from a radiation exit surface. The electromagnetic radiation of the first wavelength range thus forms the emission spectrum of the semiconductor chip and is also referred to as primary radiation. The radiation exit surface can also be referred to as the radiation-emitting surface.

The semiconductor chip is, for example, a light-emitting diode chip or a laser diode chip. The component can thus be a light-emitting diode (LED) or a laser. Preferably, the semiconductor chip has an epitaxially grown semiconductor layer sequence with an active zone that is suitable for generating electromagnetic radiation. For example, the active zone has for this a pn-junction, a double heterostructure, a single quantum well or a multiple quantum well structure.

During operation, the semiconductor chip can emit electromagnetic radiation, for example from the ultraviolet spectral range and/or from the visible spectral range, in particular from the blue spectral range. The primary radiation thus has wavelengths in the range from 400 nm to 500 nm, for example.

According to at least one embodiment, the radiation-emitting component further comprises a conversion element on a cover surface of the semiconductor chip comprising the radiation exit surface, the conversion element containing a matrix material and phosphor particles embedded therein, which convert electromagnetic radiation of the first wavelength range into electromagnetic radiation of a second wavelength range. A cover surface of the semiconductor chip is to be understood as the side facing away from a bottom surface of the semiconductor chip, which runs parallel to the main direction of extension of the semiconductor chip. In addition to the radiation exit surface, the cover surface may include areas for electrical connections, saw marks and/or dark, i.e. non-emitting, edge areas.

The term “phosphor particle” is understood here and in the following to mean a wavelength conversion material in form of particles, i.e., a material that is set up to absorb and emit electromagnetic radiation. In particular, the phosphor particles absorb electromagnetic radiation that has a different wavelength maximum than the electromagnetic radiation emitted by the phosphor particles.

For example, the phosphor particles absorb radiation with a wavelength maximum at shorter wavelengths than the emission maximum and thus emit radiation with an emission maximum that is shifted towards red. Pure scattering or pure absorption are not understood as wavelength-converting in the present case.

According to at least one embodiment, the conversion element has a bearing surface which is equal to or smaller than the cover surface of the semiconductor chip. Thus, the conversion element covers the cover surface of the semiconductor chip completely or only partially. In the case of only partial coverage, i.e., partial coating of the cover surface of the semiconductor chip with the conversion element, certain areas, for example areas for contacting the semiconductor chip such as bond pads, edge areas and/or saw marks, can remain specifically free of the conversion element.

According to at least one embodiment, the bearing surface is completely in direct contact with the cover surface of the semiconductor chip. In other words, the bearing surface of the conversion element nestles against the cover surface of the semiconductor chip without a gap, irrespective of the surface property of the cover surface of the semiconductor chip. This means that the conversion element is fixed to the cover surface of the semiconductor chip without adhesive and accordingly has a common interface with the semiconductor chip.

According to at least one embodiment, a radiation-emitting component is disclosed which comprises a semiconductor chip which, in operation, emits electromagnetic radiation of a first wavelength range from a radiation exit surface, and a conversion element on a cover surface of the semiconductor chip comprising the radiation exit surface, the conversion element containing a matrix material and phosphor particles embedded therein, which convert electromagnetic radiation of the first wavelength range into electromagnetic radiation of a second wavelength range, wherein the conversion element has a bearing surface which is equal to or smaller than the cover surface of the semiconductor chip, and the bearing surface is completely in direct contact with the cover surface of the semiconductor chip.

The inventors have recognized that the direct, i.e., adhesive-free arrangement of the conversion element on the cover surface of the semiconductor chip enables good thermal conduction of the conversion element. Conventionally, conversion platelets are used which have to be adhered to a semiconductor chip, for which silicone is usually used. However, silicone has low thermal conductivity, which creates a thermal barrier between the conversion platelet and the semiconductor chip that increases with increasing layer thickness. Such a thermal barrier can be dispensed with in the component described here due to the direct arrangement of the conversion element on the semiconductor chip. This means that the component can also be operated at high currents, for example in applications where high luminance levels are required, such as in headlights or stage lighting. Even in such so-called high-current applications, with current densities of more than 1 A/mm², the heat generated in the conversion element can be easily dissipated from it into the semiconductor chip.

The absence of an adhesive layer also can have an advantageous effect on the manufacturing of the component. For example, when a conventional pre-fabricated conversion platelet is placed on a previously applied adhesive layer, the adhesive material is squeezed out and/or reflector material, for example silicone filled with titanium dioxide, penetrates into adhesive-free cavities under the edge of the platelet. Such phenomena lead to reduced brightness, which means that an adhesive layer also represents an optical barrier. This can be avoided by using a conversion element as described here. Finally, dispensing with an adhesive layer also results in a simplified and cost-reduced manufacturing process of the component, as no adhesive process is required and fewer binning processes, i.e., processes for sorting the components according to their chromaticity coordinates, are also necessary.

Furthermore, the conversion element can only be applied to partial regions of the semiconductor chip, i.e., only defined areas of the cover surface of the semiconductor chip can be coated with the conversion element. As a result, only radiation-emitting and radiation-reflective surfaces and no (dark) light traps can be provided with the conversion element, which leads to improved efficiency of the component. With such a partial coating, for example, an approximately 10 μm to 12 μm wide edge region (mesa edge) of the cover surface of the semiconductor chip can be free of the conversion element. Areas for electrical contacting can also remain free of the conversion element and/or the radiation exit surface can only be partially coated with the conversion element.

A component described here is equally suitable for cold-white applications at e.g. 5700 K or 6500 K and for warm-white applications at e.g. 3200 K as well as for applications in which a color rendering index Ra of greater than or equal to 80, in particular greater than or equal to 90, is desired. With such a high color rendering index, there is a comparatively high red portion in the emission spectrum, whereby typical red light-emitting substances are particularly sensitive to high operating currents and operating temperatures due to the larger Stokes shift and stronger thermal quenching. Such high current densities and/or high operating temperatures can be realized with the component described here, as the conversion element described here can dissipate the heat generated well, in particular due to its direct contact with the semiconductor chip. This is a significant improvement compared to conventional conversion chips, which have silicone as a matrix material, for example, as silicone has low thermal stability and heat conductivity, which means that such conversion platelets are only suitable for applications up to 150° C. and current densities of less than 1 A/mm².

According to at least one embodiment, the bearing surface of the conversion element is equal to or smaller than the radiation exit surface.

According to at least one embodiment, the semiconductor chip has side surfaces, and the side surfaces are free of the conversion element. The side surfaces of the semiconductor chip are to be understood here and in the following as the regions that extend largely perpendicular to the main direction of extension of the semiconductor chip and connect the cover surface to the bottom surface of the semiconductor chip. In particular, the side surfaces do not include the radiation exit surface. A loss of efficiency via the side surfaces of the chip can thus be avoided.

According to at least one embodiment, the conversion element has side surfaces which have an average roughness of less than 2 μm, in particular less than 1 μm, and/or have no saw marks. In particular, the side surfaces of the conversion element run largely perpendicular to the bearing surface of the conversion element. Thus, the side surfaces of the conversion element have particularly smooth surfaces. A smooth surface of the side surfaces of the conversion element can lead to reduced emission via the side surfaces. In addition, a smooth surface of the conversion element ensures that no particles, in particular phosphor particles embedded in the matrix material of the conversion element, damage elements adjacent to the conversion element. This can be an advantage over conventionally used conversion platelets, which are singulated by cleaving or sawing and have a significantly rougher surface on their side surfaces.

According to at least one embodiment, the conversion element has side surfaces that have rounded corners. Two meeting side surfaces thus do not form a clearly defined corner which, for example, does not have a 90° angle, but a rounded corner which has a radius. Such a radius can be in the range from including 0.04 mm up to and including 0.1 mm, in particular in the range from including 0.05 mm up to and including 0.06 mm.

According to at least one embodiment, the conversion element has a cross-sectional area which tapers from the bearing surface towards the side of the conversion element facing away from the semiconductor chip. Such a conical geometry can provide a certain light guide, in particular a reduction in the radiation-emitting area and an increase in luminance, i.e. a focusing of the emitted radiation.

According to at least one embodiment, the conversion element has a cross-sectional area which tapers from a side of the conversion element facing away from the semiconductor chip towards the bearing surface. Such a conical geometry can provide a certain light guide, in particular an expansion of the emitted radiation.

According to at least one embodiment, the conversion element has a thickness that is less than or equal to 150 μm, in particular less than or equal to 100 μm. In particular, the thickness can be less than or equal to 35 μm, for example less than or equal to 25 μm. The exact thickness can be matched to the phosphor particle size and the desired degree of conversion. A thickness of less than 25 μm can be used for cold-white emission, for example, while a thickness of around 80 μm to 90 μm can be selected for orange tones. This allows the conversion element to be particularly thin, which leads, for example, to reduced side emission and ensures good thermal bonding of the conversion element to the semiconductor chip. The thickness of the conversion element described here is particularly reduced compared to previously used conversion platelets, which are generated on a glass plate or a film and are only attached to the semiconductor chip by means of an adhesive layer after completion.

According to at least one embodiment, the conversion element has a thickness that is greater than or equal to 10 μm.

According to at least one embodiment, the conversion element has a solids content of greater than or equal to 45% by volume, in particular greater than or equal to 50% by volume. According to one embodiment, the solids content is formed by solid particles that are up to 100% phosphor particles. This means that the matrix material has a high solids content, which has a positive effect on the temperature, radiation and chemical resistance of the conversion element. In addition to phosphor particles, the solids content can be made up of microparticles/fillers and/or nanoparticles/fillers. In other words, the phosphor particles may be partially replaced by non-converting micro- or nanoparticles, for example to be able to adjust and/or control the chromaticity coordinate while maintaining the same thickness of the conversion layer. For example, the conversion element is long-term stable at up to 220° C. and up to 6 W/mm².

According to at least one embodiment, the matrix material has an organic content which is less than 40% by weight, in particular less than 20% by weight. A low organic content contributes in particular to the long-term stability of the conversion element and thus of the component.

According to at least one embodiment, the matrix material has a Shore D hardness that is greater than 50. This means that the conversion element, for example the side of the conversion element facing away from the semiconductor chip, can be easily reworked, for example ground or polished. Modifications of the conversion element, for example on the side of the conversion element facing away from the semiconductor chip, are also conceivable. For example, this conversion element can be well provided with a further layer, a small platelet or a structuring. In addition, the conversion element has a high mechanical stability due to its hardness, which can be advantageous, for example, if conversion elements that have already been applied are to be separated from each other by sawing.

According to a further embodiment, the matrix material comprises a three-dimensionally cross-linked polyorganosiloxane. Such a polyorganosiloxane is derived from a precursor material which has a curing temperature that does not damage the semiconductor chip and binds or adheres well to it. Such a curing temperature is, for example, less than or equal to 220° C. Thus, to produce the conversion element, a precursor material of the matrix material can be applied directly to the semiconductor chip and be cured there. In particular, this results in an improved and more efficient thermal bonding of the conversion element to the semiconductor chip compared to conventional components. Furthermore, the three-dimensionally cross-linked polyorganosiloxane can be formed without cracks or pores after curing, especially if it has a high solids content of greater than or equal to 45% by volume. A three-dimensionally cross-linked polyorganosiloxane also has good thermal conductivity, especially if it has a low organic content, for example less than 40% by weight.

Furthermore, it is possible to fill the three-dimensionally cross-linked polyorganosiloxane with a high proportion of phosphor particles, in particular with a proportion of greater than 45% by volume, and thus efectuate a high temperature, radiation and chemical resistance of the conversion element. After its curing, the three-dimensionally cross-linked polyorganosiloxane has sufficient hardness to allow further mechanical processing and/or modification of the conversion element. The thickness of the conversion element can also be precisely adjusted, for example by grinding, and thus in particular the exact chromaticity coordinate of the converted radiation can be set.

According to at least one embodiment, the three-dimensionally crosslinked polyorganosiloxane has the following repeating unit:

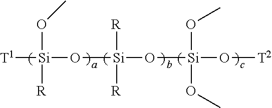

In this general formula, a +b+c=1, 0.65≤a≤1 and 0≤ b+c≤0.35 with 0≤b<0.35 and 0≤c<0.35. Furthermore, R is independently selected from methyl, phenyl and combinations thereof. T¹ and T² are independently selected from methyl, methoxy and combinations thereof. The . . . represent the linking points to further repeating units.

The three-dimensionally cross-linked polyorganosiloxane also enables the embedding of various phosphor particles.

According to at least one embodiment, the phosphor particles are selected from the group:
(RE₁₋ₓCeₓ)₃(Al_{1-y}A′_{y})₅O₁₂ with 0<x≤0.1 and 0≤y≤1,
(RE₁₋ₓCeₓ)₃(Al_{5-2y}Mg_{y}Si_{y})O₁₂ with 0<x<0.1 and 0≤y ≤2,
(RE₁₋ₓCeₓ)₃Al_{5-y}Si_{y}O_{12-y}N_{y} with 0<x≤0.1 and 0≤y≤0.5,
(RE₁₋ₓCeₓ)₂CaMg₂Si₃O₁₂: Ce³⁺ with 0<x≤0.1,
(AE₁₋ₓEuₓ)₂Si₅N₈ with 0<x≤0.1,
(AE₁₋ₓEuₓ)AlSiN₃ with 0<x≤0.1,
(AE₁₋ₓEuₓ)₂Al₂Si₂N₆ with 0<x≤0.1,
(Sr₁₋ₓEuₓ)LiAl₃N₄ with 0<x≤0.1,
(AE₁₋ₓEuₓ)₃Ga₃N₅ with 0<x≤0.1,
(AE₁₋ₓEuₓ)Si₂O₂N₂ with 0<x≤0.1,
(AEₓEu_{y})Si_{12-2x-3y}Al_{2x+3y}O_{y}N_{16-y} with 0.2≤x≤2.2 and 0<y≤0.1,
(AE₁₋ₓEuₓ)₂SiO₄ with 0<x≤0.1,
(AE₁₋ₓEuₓ)₃Si₂O₅ with 0<x≤0.1,
K₂(Si_{1-x-y}Ti_{y}Mnₓ)F₆ with 0<x≤0.2 and 0<y≤1−x,
(AE₁₋ₓEuₓ)₅(PO₄)₃Cl with 0<x≤0.2,
(AE₁₋ₓEuₓ)Al₁₀O₁₇ with 0<x≤0.2
and combinations thereof. RE is at least one of Y, Lu, Tb and Gd, AE is at least one of Mg, Ca, Sr, Ba, A′ is at least one of Sc and Ga, whereby the phosphor particles can optionally contain one or more halogens.

Thus, the three-dimensionally cross-linked polyorganosiloxane allows similar flexibility in terms of the choice of the chromaticity coordinate as a conventional silicone matrix, and superior flexibility in terms of the choice of the chromaticity coordinate compared to conversion ceramics as well as to converters in which phosphor particles are embedded in glass, but has an improved optical and thermal performance and temperature resistance compared to a conventional silicone matrix.

According to at least one embodiment, the three-dimensionally crosslinked polyorganosiloxane is produced from a precursor material comprising an alkoxy-functionalized, in particular methoxy-functionalized polyorganosiloxane resin. The three-dimensionally crosslinked polyorganosiloxane produced therefrom thus has a low organic content of less than 40% by weight, in particular less than 20% by weight.

According to at least one embodiment, the precursor material has the following repeating unit:

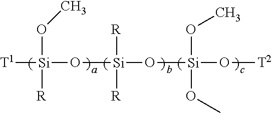

In this general formula, a +b+c=1, 0.65≤a≤1 and 0≤b+c≤0.35 with 0≤b<0.35 and 0≤c<0.35. Furthermore, R is independently selected from methyl, phenyl and combinations thereof. T¹ and T² are independently selected from methyl, methoxy and combinations thereof. The . . . represent the linking points to further repeating units.

According to at least one embodiment, the conversion element further comprises filler substances. The filler substances can be selected from the group
Oxides, for example SiO₂, in particular nano-SiO₂ and micro-SiO₂, ZrO₂, TiO₂, Al₂O₃ and Zno, nitrides, for example AlN, Si₃N₄, BN and GaN,
Carbon-based filler substances, for example carbon nanotubes, graphene and their derivatives, heteropolyacids, for example 12-tungstophosphoric acid (H₃P₁₂WO₄₀) and 12-tungstosilicylic acid (H₄SiW₁₂O₄₀),
organometallic components, for example alkoxides of silicon, titanium, zirconium, aluminum and/or hafnium,
organic molecules, such as adhesion promoters, defoamers, thickeners, diluents and plasticizers,
organic and inorganic polymers, for example poly(dimethylsiloxane), poly(methylphenylsiloxane), poly(diphenylsiloxane) and polysilsesquioxane (PSQ),
   and combinations thereof can be selected. The above-mentioned inorganic nanoparticles can be provided with coating material on their surface in order to achieve better miscibility with the precursor material for producing the matrix material of the conversion element.

According to at least one embodiment, the component has connections for electrical contacting, wherein the connections are present on the side of the semiconductor chip facing away from the radiation exit surface. This means that the connections are present on the non-emitting side of the semiconductor chip and can be soldered or glued on there in a conductive manner. Such a semiconductor chip can also be referred to as a flip chip and can be easily combined with the conversion element described here.

According to at least one embodiment, the component has connections for electrical contacting, wherein the connections are present on the side of the semiconductor chip facing the radiation emission surface. Such semiconductor chips have, in particular, an insulating bond or soldering to their base, for example a substrate, and can be easily combined with the conversion element described here.

According to at least one embodiment, the component comprises connections for electrical contacting, wherein the connections are present on the side of the semiconductor chip facing away from the radiation exit surface and on the side of the semiconductor chip facing the radiation exit surface. The connections are therefore located on different sides of the semiconductor chip. For example, a bond pad is located on the side of the semiconductor chip facing the radiation exit surface and a conductive soldering or bonding is located on the side of the semiconductor chip facing away from the radiation exit surface. Such a semiconductor chip can also be combined well with the conversion element described here.

The possibility of combining the conversion element described here with different semiconductor chip types is based, among other things, on the fact that the conversion element can be applied as a partial coating and thus dark areas, in particular edge areas, and/or areas for contacting the semiconductor chip can be left free of the conversion element.

A method for producing a component is further disclosed. The method is particularly suitable for producing a component described herein. All the features mentioned in connection with the component thus also apply to the method and vice versa.

According to at least one embodiment, at least one semiconductor chip is provided in the method, which emits electromagnetic radiation of a first wavelength range from a radiation exit surface during operation. By at least one semiconductor chip it should be understood that the method can be used to provide a single semiconductor chip with a conversion element as well as several semiconductor chips simultaneously. If several semiconductor chips are provided with conversion elements at the same time, the semiconductor chips can also be connected to each other and singulated after the conversion elements have been applied. The method thus enables multi-chip coating.

According to at least one embodiment, the method further comprises depositing a precursor material in which phosphor particles are embedded which convert electromagnetic radiation of the first wavelength range into electromagnetic radiation of a second wavelength range. The deposition takes place directly on at least one region of a cover surface of the semiconductor chip comprising the radiation exit surface.

A precursor material is a material that reacts through a chemical reaction initiated by external influences to form the desired material that is present in the finished component. External influences may include, for example, an increase in temperature or irradiation. The precursor material may be, for example, alkoxy-functionalized, in particular methoxy-functionalized polyorganosiloxane resin. Such precursor materials can react to form a three-dimensionally cross-linked polyorganosiloxane.

Direct deposition means that the precursor material is brought into direct contact with the cover surface of the semiconductor chip so that it has a common interface with the semiconductor chip and conforms to the cover surface of the semiconductor chip without a gap. An adhesive layer can therefore be dispensed with. This is made possible in particular by the fact that the precursor material has a certain stickiness, which ensures that the precursor material is fixed to the desired region of the semiconductor chip.

“On at least part of a cover surface” is intended to mean that the entire cover surface of the semiconductor chip is coated with the precursor material or that only a partial coating takes place, in which specific areas of the cover surface of the semiconductor chip are left free of precursor material.

According to at least one embodiment, the precursor material is deposited by a method selected from doctor blading, spraying and printing. According to at least one embodiment, the precursor material in which the phosphor particles are embedded in is deposited in the form of a homogeneous mixture, wherein the mixture may comprise further filler substances. Possible filler substances as well as phosphor particles have already been mentioned in relation to the component and also apply to the method.

According to at least one embodiment, the method further comprises curing the precursor material to form a conversion element comprising a matrix material (5) and the phosphor particles (1) embedded therein, wherein the conversion element has a bearing surface which is equal to or smaller than the cover surface of the semiconductor chip, and the bearing surface is completely in direct contact with the cover surface of the semiconductor chip. During the curing process, from the precursor material is thus formed the matrix material in which the phosphor particles are embedded and which is largely or completely free of pores and cracks. The conversion element is then fixed to the region of the cover surface of the semiconductor chip to which the precursor material was previously deposited.

According to at least one embodiment, a method for producing a radiation-emitting component is disclosed, comprising the method steps of
providing at least one semiconductor chip which, in operation, emits electromagnetic radiation of a first wavelength range from a radiation exit surface,
deposition of a precursor material, in which phosphor particles are embedded, which convert electromagnetic radiation of the first wavelength range into electromagnetic radiation of a second wavelength range, directly onto at least one region of a cover surface of the semiconductor chip comprising the radiation exit surface,
curing the precursor material to form a conversion element comprising a matrix material (5) and the phosphor particles (1) embedded therein, wherein the conversion element has a bearing surface which is equal to or smaller than the cover surface of the semiconductor chip, and the bearing surface is completely in direct contact with the cover surface of the semiconductor chip.

The method is particularly simple and cost-effective to implement, as there is no need for an adhesive layer between the semiconductor chip and the conversion element. An adhesive process is therefore not necessary. In addition, there is no adhesive layer in the produced component that would represent a thermal and/or optical barrier between the conversion element and the semiconductor chip. Furthermore, the precursor material can be deposited specifically onto emitting and/or reflective regions of the semiconductor chip, thus mapping the geometry of the active region and, for example, leaving dark edge regions free of the conversion element. This leads to a reduction in efficiency loss. Further advantages of the component produced using the method described here have already been presented with regard to the component and apply equally to the component produced using the method.

According to at least one embodiment, curing is carried out at a temperature that is less than or equal to 220° C. This means that a temperature is used for curing that has no damaging effect on the semiconductor chip and temperature-sensitive light-emitting substances such as nitride phosphors. According to one embodiment, curing takes place for a time period of less than or equal to 5 hours, in particular less than or equal to 2 hours.

According to at least one embodiment, a plurality of semiconductor chips are provided, which are singulated after the deposition and curing of the precursor material. A multi-chip coating can thus be realized with the method.

Furthermore, singulating leads to semiconductor chips with conversion elements arranged on them, which have smooth side surfaces. After singulation, the side surfaces of the conversion element have a roughness of less than 2 μm, in particular less than 1 μm. Due to the hardness of the matrix material, the conversion elements can be easily separated mechanically, for example by sawing. Alternatively, separation or singulation of the conversion elements is not necessary at all if the precursor material is deposited in such a way that the bearing surface of the conversion element is smaller than the cover surface of the semiconductor chip. In this case, only the semiconductor chips are singulated. This variant also provides conversion elements that already have their smooth side surfaces as a result of the manufacturing process. If only the semiconductor chips have to be singulated, this again leads to a cost advantage, as the sawing of the conversion elements and the associated wear are avoided. Furthermore, components with particularly good optical performance can be provided due to the very smooth side surfaces of the conversion elements.

According to at least one embodiment, the thickness and shape of the conversion element is adjusted during the deposition and/or curing of the precursor material. For example, the precursor material can be applied to at least regions of the cover surface of the semiconductor chip, pre-cured there at a first temperature and in this state mechanically, for example by grinding, brought to the desired thickness. The material can then be fully cured at a second temperature, which is in particular higher than the first temperature, to form the matrix material.

Alternatively or additionally, the precursor material can be structured during deposition. This can be done using a lithography process, for example. For example, before the precursor material is deposited, a photoresist layer can be applied to the cover surface of the semiconductor chip and structured by means of exposure. The precursor material can then be filled into the resulting structures, i.e. into the areas on the cover surface of the semiconductor chip that are free of photoresist layer, and pre-cured. After a further step, in which the structured photoresist layer is chemically removed, for example, complete curing can take place. Such a method can be used in particular to generate a conical geometry and/or rounded corners of the conversion element as already described above. For example, the structured photoresist layer can form a mask and the resulting conversion element can have a cross-sectional area that widens in a direction away from the semiconductor chip. According to another example, a conversion element can be generated by means of a so-called LDI (laser direct imaging) process, which has a cross-sectional area that tapers in a direction away from the semiconductor chip.

According to at least one embodiment, the precursor material cross-links three-dimensionally during curing. In particular, if an alkoxy-functionalized polyorganosiloxane resin is used as the precursor material, a three-dimensional SiO₂ network with a low proportion of less than 40% by weight, in particular less than 20% by weight, of organic remainders is formed during curing. Solid particles, up to 100% of which are phosphor particles, are embedded in this network. The solids content in the conversion element is, for example, at least 45% by volume, in particular at least 50% by volume.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed herein. Further aspects and embodiments of the present disclosure will be described below in conjunction with the figures, wherein:

FIG. 1 shows schematic cross-sectional views of conversion elements according to exemplary embodiments.

FIGS. 2, 3A to 3C, 4A to 4C, 5 and 6 show schematic cross-sectional views of components according to exemplary embodiments.

FIGS. 3D and 4D show top views of components according to exemplary embodiments.

FIGS. 7 and 8 show light microscope images of conversion elements according to exemplary embodiments.

FIGS. 9A to 9C show schematic cross-sections of components according to various exemplary embodiments.

### DETAILED DESCRIPTION

In the exemplary embodiments and figures, identical, similar or similarly acting elements may each be provided with the same reference signs. The elements shown and their relative sizes are not to be regarded as true to scale; rather, individual elements, such as layers, elements, components and areas, may be shown in exaggerated size for better visualization and/or better understanding.

To produce a component according to an exemplary embodiment, a semiconductor chip 10, in particular an LED chip or a plurality of semiconductor chips in the form of a chip wafer, is provided. A precursor material in which phosphor particles 1 are embedded, or a homogeneous mixture containing the precursor material in which phosphor particles 1 are embedded, is deposited directly to the cover surface 12 of the semiconductor chip or chips 10.

The precursor material is a methoxy-functionalized polyorganosiloxane resin that has the following repeating unit:

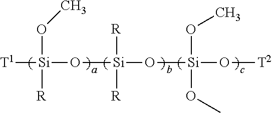

There, it is a +b+c=1, 0.65≤a≤1 and 0≤b+c≤0.35 with 0≤b<0.35 and 0≤c<0.35. Furthermore, R is independently selected from methyl, phenyl and combinations thereof. T¹ and T² are independently selected from methyl, methoxy and combinations thereof. The . . . represent the linkage points to further repeating units. A homogeneous mixture comprising the precursor material and further comprising nano-SiO₂ to adjust the rheology and micro-SiO₂ as filler substances to improve processing is prepared. The mixture also comprises phosphor particles 1, which are selected from the group:
(RE₁₋ₓCeₓ)₃(Al_{1-y}A′_{y})₅O₁₂ with 0<x≤0.1 and 0≤y≤1,
(RE₁₋ₓCeₓ)₃(Al_{5-2y}Mg_{y}Si_{y})O₁₂ with 0<x<0.1 and 0≤y≤2,
(RE₁₋ₓCeₓ)₃Al_{5-y}Si_{y}O_{12-y}N_{y} with 0<x≤0.1 and 0≤y≤0.5,
(RE₁₋ₓCeₓ)₂CaMg₂Si₃O₁₂: Ce³⁺ with 0<x≤0.1,
(AE₁₋ₓEuₓ)₂Si₅N₈ with 0<x≤0.1,
(AE₁₋ₓEuₓ)AlSiN₃ with 0<x≤0.1,
(AE₁₋ₓEuₓ)₂Al₂Si₂N₆ with 0<x≤0.1,
(Sr₁₋ₓEuₓ)LiAl₃N₄ with 0<x≤0.1,
(AE₁₋ₓEuₓ)₃Ga₃N₅ with 0<x≤0.1,
(AE₁₋ₓEuₓ)Si₂O₂N₂ with 0<x≤0.1,
(AEₓEu_{y})Si_{12-2x-3y}Al_{2x+3y}O_{y}N_{16-y} with 0.2≤x≤2.2 and 0<y≤0.1,
(AE₁₋ₓEuₓ)₂SiO₄ with 0<x≤0.1,
(AE₁₋ₓEuₓ)₃Si₂O₅ with 0<x≤0.1,
K₂(Si_{1-x-y}Ti_{y}Mnₓ)F₆ with 0<x≤0.2 and 0<y≤1−x,
(AE₁₋ₓEuₓ)₅(PO₄)₃Cl with 0<x≤0.2,
(AE₁₋ₓEuₓ)Al₁₀O₁₇ with 0<x≤0.2
   and combinations thereof. RE is at least one of Y, Lu, Tb and Gd, AE is at least one of Mg, Ca, Sr, Ba, A′ is at least one of Sc and Ga, whereby the phosphor particles can optionally contain one or more halogens.

The mixture is deposited directly by doctor blading, printing or spraying to regions of the cover surface 12 (partial coating) or to the entire cover surface 12 of the semiconductor chip or chips 10. In the case of a partial coating, for example, the areas of the semiconductor chip 10 that are to remain free of a conversion element 20 are protected by a photoresist, which is removed again after the precursor material has been deposited and pre-cured.

After deposition of the precursor material or the mixture containing the precursor material, the precursor material is cured to form a three-dimensionally cross-linked polyorganosiloxane as matrix material 5. Curing takes place at a temperature of less than or equal to 220° C. The three-dimensionally cross-linked polyorganosiloxane has the following repeating unit:

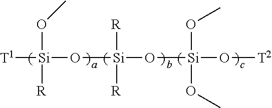

In this general formula, a+b+c=1, 0.65≤a≤1 and 0≤ b+c≤0.35 with 0≤b<0.35 and 0≤c<0.35. Furthermore, R is independently selected from methyl, phenyl and combinations thereof. T¹ and T² are independently selected from methyl, methoxy and combinations thereof. The . . . represent the linking points to further repeating units.

The thickness of the conversion element 20 produced in this way is 10 μm to 150 μm, depending on the desired chromaticity coordinate.

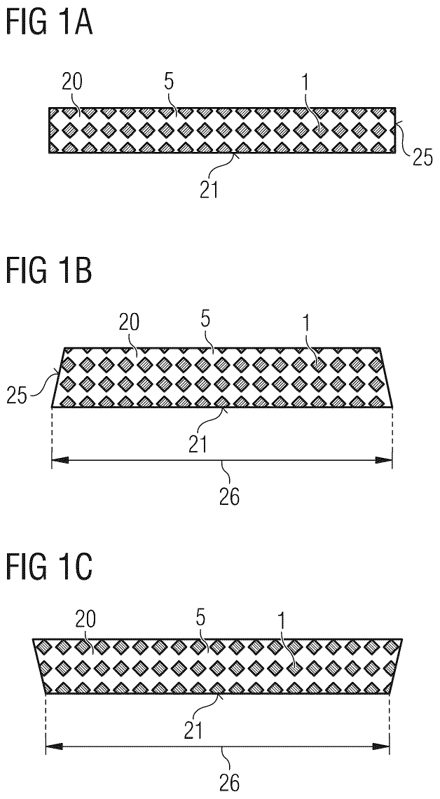

FIG. 1 shows cross-sections of exemplary embodiments of conversion elements 20 which are produced as explained above. For better visualization of details, the conversion elements 20 are shown here without the semiconductor chips 10 to which they are directly applied.

A conversion element 20 contains a matrix material 5 in which the phosphor particles 1 are embedded. FIG. 1A also shows the bearing surface 21, which is in direct contact with the cover surface 12 of the semiconductor chip 10 (not shown here). The conversion element 20 of FIG. 1A has plane-parallel side surfaces 25, which are perpendicular to the bearing surface 21.

FIGS. 1B and 1C show two alternative geometries of the conversion element 20. In contrast to FIG. 1A, the cross-sectional area 26 of the conversion element is also shown here, which in FIG. 1B tapers from the bearing surface 21 to the side opposite the bearing surface 21 (the side facing away from the semiconductor chip 10). Such a conical geometry enables, for example, radiation focusing during operation of the component 100. In FIG. 1C, the conversion element 20 also has a conical geometry, but the cross-sectional area 26 of the conversion element 20 increases with increasing distance from the bearing surface 21. Such a geometry enables, for example, radiation broadening during operation of the component 100.

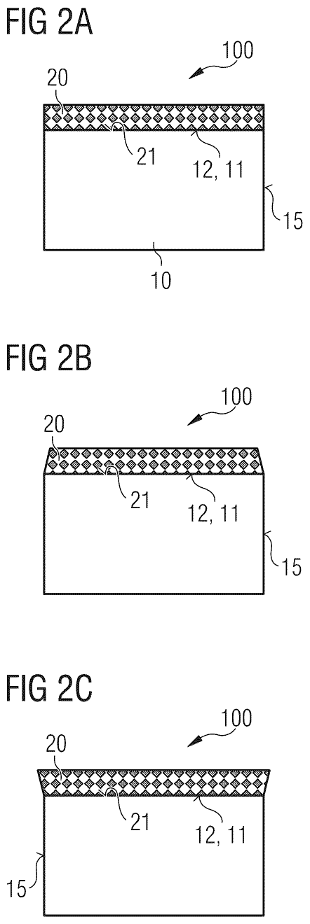

FIGS. 2A to 2C shows schematic cross-sections of exemplary embodiments of components 100 which contain the conversion elements 20 shown in FIG. 1. In each case, a semiconductor chip 10 is shown, on the cover surface 12 of which the bearing surface 21 of the conversion element 20 is applied in direct contact, nestled without adhesives and without gaps. This ensures good heat conduction between conversion element 20 and semiconductor chip 10. The cover surface 12 also comprises the radiation exit surface 11 of the semiconductor chip 10, but can also be larger than this. FIG. 2A shows the component 100 with the conversion element 20 according to FIG. 1A. FIG. 2B shows the component 100 with the conversion element 20 according to FIG. 1B, and FIG. 2C shows the component 100 with the conversion element 20 according to FIG. 1C. Also shown are the side surfaces 15 of the semiconductor chip 10, which are free of the conversion element 20.

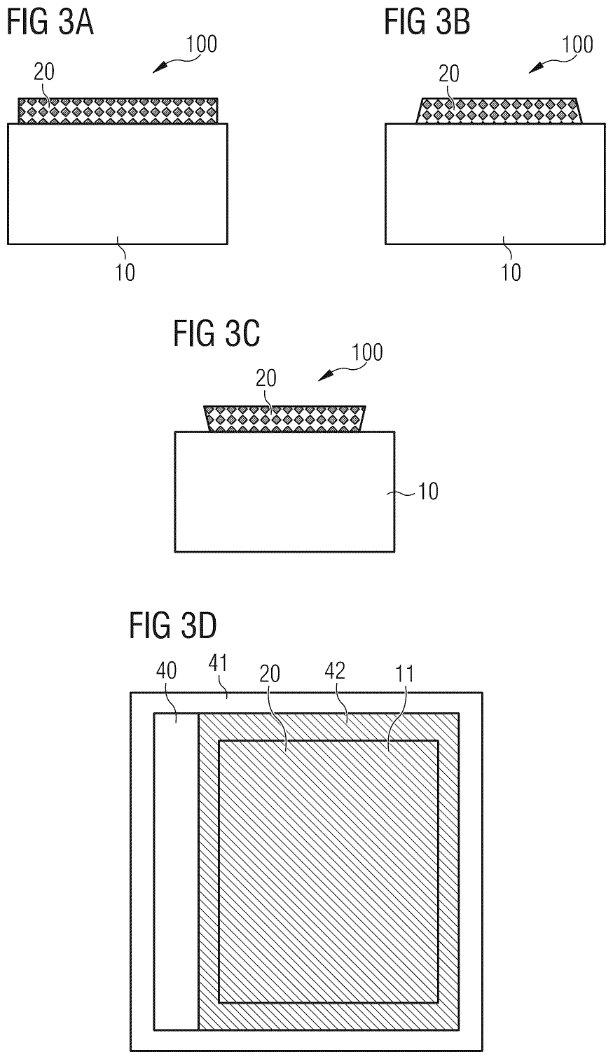

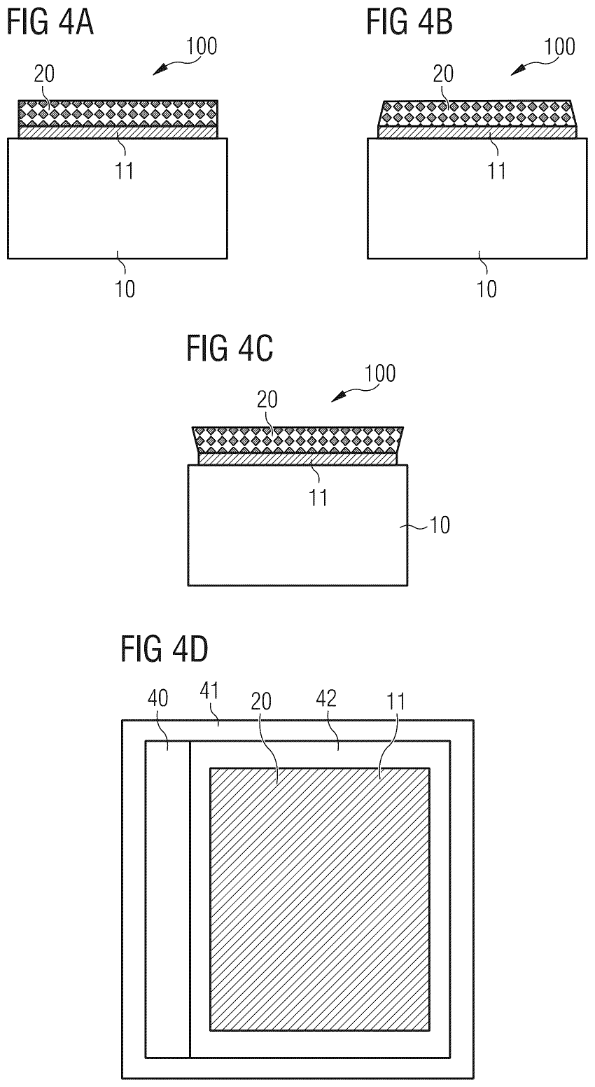

FIGS. 3A to 3C and FIGS. 4A TO 4C show schematic cross-sections of components 100 in which the conversion element 20 is applied to the semiconductor chip 10 as a partial coating in each case. For the sake of clarity, not all the reference signs shown in FIGS. 1A to 1C and 2A to 2C are shown here, but they apply analogously to FIGS. 3 and 4. FIGS. 3D and 4D each show the components 100 in top view.

FIGS. 3A and 4A show the conversion element 20 of FIG. 1A, FIGS. 3B and 4B show the conversion element 20 of FIG. 1B and FIGS. 3C and 4C show the conversion element 20 of FIG. 1C on the semiconductor chip 10. In each case, the conversion element 20 is applied to the semiconductor chip 10 as a partial coating. According to the top view in FIG. 3D, areas for electrical connections 40 (bond pads or bond bars) and saw markds 41 are free of the conversion element 20. The conversion element 20 covers the radiation exit surface 11 and dark edge areas (mesa edges) 42 of the cover surface of the semiconductor chip 10 and is shown hatched for clarity.

In FIG. 4, the conversion element 20 extends only to the radiation exit surface 11, which is shown as a hatched layer for clarification in FIGS. 4A to 4C. FIG. 4D shows this arrangement of the conversion element 20 again in a top view of the component 100, where the conversion element 20 is shown hatched.

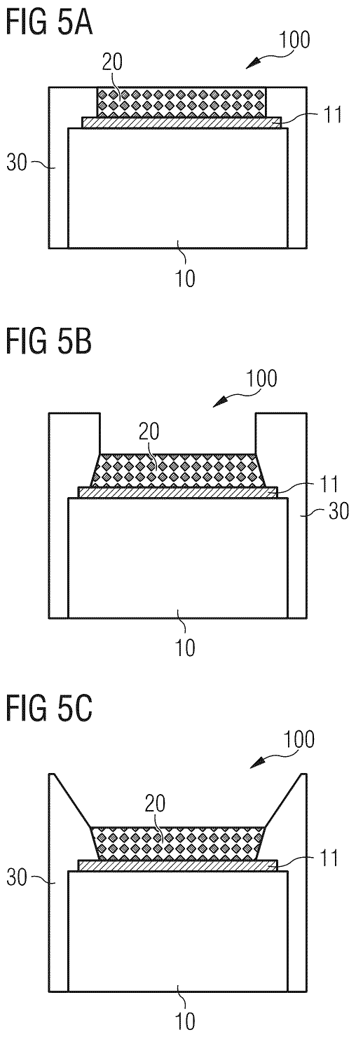

FIG. 5 shows a further variant of the component 100. Here, the conversion element 20 extends only to a partial region of the radiation exit surface 11, which is again shown as an additional layer in FIGS. 5A to 5C for illustration purposes. The conversion element according to FIG. 1A is located on the semiconductor chip 10 of FIG. 5A, the conversion element according to FIG. 1B is located on the semiconductor chip 10 of FIG. 5B, and the conversion element according to FIG. 1C is located on the semiconductor chip 10 of FIG. 5C.

Another difference to the components 100 of the previous figures is that in FIG. 5 a potting 30 is shown, which laterally encloses both the semiconductor chip 10 and the conversion element 20. The potting 30 can have different geometries and filling heights. The potting 30 can be flush with the conversion element 20, as shown in FIG. 5A, or project beyond the conversion element 20 (FIGS. 5B and 5C).

Furthermore, the potting 30 can have plane-parallel side walls (FIG. 5A) or have sloped side walls in the direction of the conversion element 20 (FIGS. 5B and 5C). The potting can be formed of silicone or epoxy resin, for example, and optionally filled with TiO₂, for example. In a further configuration, other filler substances may also be included in addition to TiO₂, for example.

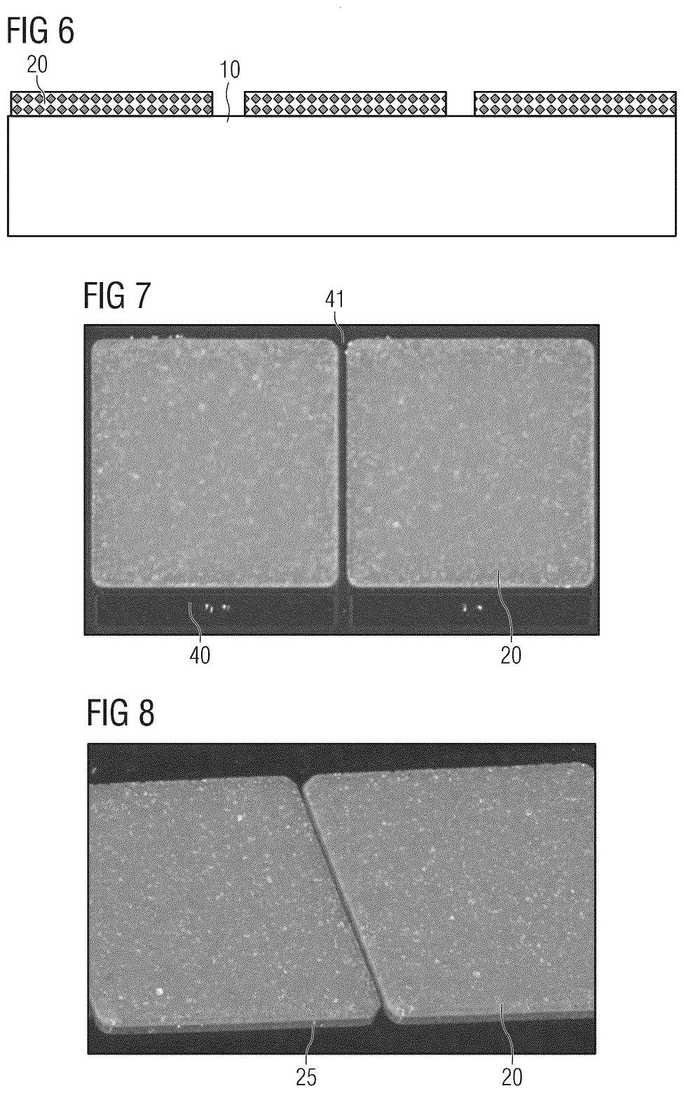

FIG. 6 shows a schematic cross-section of a semiconductor chip wafer, as a plurality of contiguous semiconductor chips 10 to which conversion elements 20 have already been applied. After singulation, a plurality of components 100 are thus obtained by means of multichip coating.

FIG. 7 shows a top view of a conversion element 20 under a light microscope. It can be seen that the area for electrical connections 40 (bond bars) and saw marks 41 is free of conversion element 20. The conversion element 20 thus only covers the radiation exit surface 11. The size of the conversion element 20 is approximately 1 mm². The underlying semiconductor chip 10 is not yet singulated in this image, so the conversion elements 20 were produced by means of multichip coating. The corners of the conversion element 20 are rounded and the side surfaces 25 of the conversion elements 20 appear straight and intact, i.e. no chipping can be seen.

FIG. 8 shows conversion elements 20 comparable to FIG. 7 still in inclined view before singulation of the semiconductor chip 10, i.e. after multichip coating. These are conversion elements 20 which have a geometry as described with respect to FIG. 1B and have a size of approximately 1 mm². In addition to the rounded corners, the smooth, clearly structured and intact side surfaces 25 of the conversion element can also be seen here. The thickness of the conversion element in this case is 25-30 μm. Garnet phosphor particles 1 are embedded in it for a cold-white application.

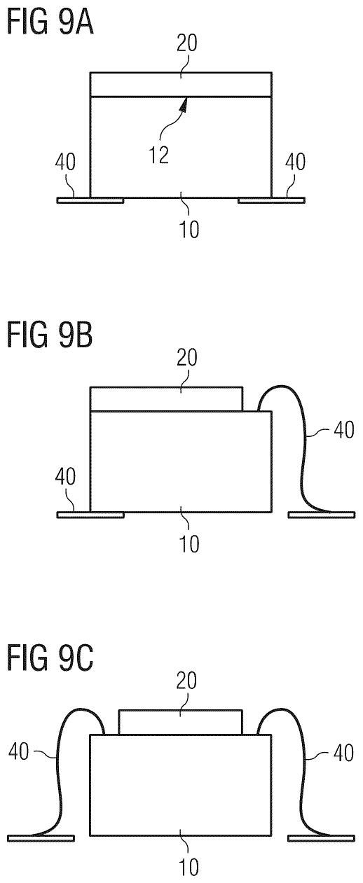

FIG. 9 shows a schematic cross-section of components 100 with different types of semiconductor chips 10, which can be combined with the conversion elements 20 described here. In each of FIG. 9A to 9C, conversion elements 20 according to FIG. 1A are applied to the semiconductor chip 10. However, any combination of conversion elements 20 described here with the various semiconductor chip types is also possible. In FIG. 9A to 9C, the semiconductor chips 10 are each provided with electrical connections 40, both of which can be present on the side of the semiconductor chip 10 facing away from the cover surface 12 (flip-chip design, FIG. 9A). In this case, the cover surface 12 can be completely covered by the conversion element 20, but a partial coating is also conceivable. The electrical connections 40 can also be present on the cover surface 12 and on the side of the semiconductor chip 10 facing away from the cover surface 12 (FIG. 9B) and both can be present on the cover surface 12 of the semiconductor chip (FIG. 9C).

Exemplary embodiment 1: Component 100 with LED flip chip 10 with conversion element 20 for cold-white applications A homogeneous mixture containing alkoxy-functionalized polyorganosiloxane resin as precursor material, nano-SiOs, optionally micro-SiO₂ and phosphor particles 1, which comprise one or more yellow-emitting garnet phosphors for generating a cold-white emission, is sprayed over the entire cover surface 12 of an LED semiconductor chip 10 in flip-chip design (i.e. all electrical connections 40 for electrical contact are present on the side of the semiconductor chip 10 facing away from the conversion element 20) or of an LED semiconductor chip wafer in flip-chip design and cured at a maximum of 150° C. for several hours. The layer thickness of the resulting conversion element 20 for this chromaticity coordinate is 10 to 100 μm, depending on the exact composition and grain size of the phosphor particles 1. The deposition of the homogeneous mixture is also possible by a doctor blade process or printing.

If regions of the cover surface 12 are to be free of the conversion element 20, this can also be partially removed there again. Alternatively, these areas can also be protected by a photoresist, which is removed again after the homogeneous mixture has been deposited and the conversion element 20 has been formed.

A subsequent surface coating of the conversion element 20 with, for example, an optical coating (such as an anti-reflective coating (AR) or a coating to improve the color over angle (COA)) is possible. Depending on the desired properties, the surface of the conversion element 20 facing away from the semiconductor chip 10 can be made rough or smooth, and the thickness of the conversion element 20 can be readjusted.

Exemplary embodiment 2: Component 100 with LED semiconductor chip 10 with electrical connection 40 on the cover surface 12 and on the side of the semiconductor chip 10 facing away from the cover surface 12 and with conversion element 20 on the cover surface 12 for cold-white applications

All areas of the cover surface 12 of the semiconductor chip 10 that are to remain without conversion element 20, such as the bond pad/bar as electrical connection 40 for the electrical contacting on the cover surface 12 of the semiconductor chip 10, and optionally the saw marks 41 and optionally the dark non-light-emitting areas on the cover surface 12 of the semiconductor chip 10, are protected by a photoresist. Then, a homogeneous mixture comprising alkoxy-functionalized polyorganosiloxane resin as precursor material, nano-SiO₂, optionally micro-SiO₂, and phosphor particles 1 comprising one or more yellow-emitting garnet phosphors to generate a cold-white emission is deposited to the cover surface 12 of an LED semiconductor chip 10 or LED semiconductor chip wafer by a doctor blade process or printing and cured at a maximum of 120° C. for one hour. After removing the photoresist, the resulting conversion element 20 can be post-cured again at a higher temperature, for example at 220° C. The layer thickness of the conversion element for this chromaticity coordinate is 10 to 100 μm, depending on the exact composition and grain size of the phosphor particles 1. The homogeneous mixture can also be deposited by spraying.

Alternatively, a complete coating of the cover surface 12 with the homogeneous mixture in combination with a subsequent partial removal of the conversion element 20 is also conceivable.

A subsequent surface coating of the conversion element 20 with, for example, an optical coating (such as an anti-reflective coating (AR) or a coating to improve the color over angle (COA)) is possible. Depending on the desired properties, the surface of the conversion element 20 facing away from the semiconductor chip 10 can be made rough or smooth, and the thickness of the conversion element 20 can be readjusted.

Exemplary embodiment 3: Component 100 with LED semiconductor chip 10 with electrical connection 40 on the cover surface 12 and on the side of the semiconductor chip 10 facing away from the cover surface 12 and with conversion element 20 on the cover surface 12 for orange (amber) applications

The component is produced as in exemplary embodiment 2, but with a phosphor mixture for amber (green and red emitting phosphor particles 1). The layer thickness of the conversion layer for this chromaticity coordinate is 30 to 150 μm, depending on the exact composition and grain size of the phosphor particles.

A subsequent surface coating of the conversion element 20 with, for example, an optical coating (e.g. an anti-reflective coating (AR) is possible. Depending on the desired properties, the surface of the conversion element 20 facing away from the semiconductor chip 10 can be made rough or smooth, and the thickness of the conversion element 20 can be readjusted.

Exemplary embodiment 4: Component 100 with LED semiconductor chip 10 with electrical connection 40 only on the cover surface 12 with conversion element 20 for warm-white applications

The component is produced in the same way as in exemplary embodiment 3, but with a different type of chip with regard to the electrical connections 40 and with a phosphor mixture for warm-white containing one or more different green and red emitting phosphor particles 1. The layer thickness of the conversion element 20 for this chromaticity coordinate is 20 to 120 μm, depending on the exact composition and grain size of the phosphor particles 1.

A subsequent surface coating of the conversion element 20 with, for example, an optical coating (such as an anti-reflective coating (AR) or a coating to improve the color over angle (COA)) is possible. Depending on the desired properties, the surface of the conversion element 20 facing away from the semiconductor chip 10 can be made rough or smooth, and the thickness of the conversion element 20 can be readjusted.

The subsequent surface coating can also be a multiple coating, i.e. several identical or different coatings can be applied to the conversion element 20.

The features and exemplary embodiments described in connection with the figures can be combined with one another according to further exemplary embodiments, even if not all combinations are explicitly described. Furthermore, the exemplary embodiments described in connection with the figures may alternatively or additionally have further features as described in the general part.

The present disclosure is not limited to the description based on the exemplary embodiments. Rather, the present disclosure includes any new feature as well as any combination of features, which includes in particular any combination of features in the patent claims, even if this feature or combination itself is not explicitly stated in the patent claims or exemplary embodiments.

### REFERENCE SIGNS

1 Phosphor particles
5 Matrix material
10 Semiconductor chip
11 Radiation exit surface
12 Cover surface
15 Side surface of the semiconductor chip
20 Conversion element
21 bearing surface
25 Side surface of the conversion element
26 Cross-sectional area of the conversion element
30 Potting
40 Connection
41 Saw mark
42 Border area
100 Component

What is claimed is:

1. A radiation-emitting component, comprising:
a semiconductor chip which, during operation, is configured to emit electromagnetic radiation of a first wavelength range from a radiation exit surface, and
a conversion element on a cover surface of the semiconductor chip comprising the radiation exit surface, the conversion element containing a matrix material and phosphor particles embedded therein, which convert electromagnetic radiation of the first wavelength range into electromagnetic radiation of a second wavelength range,
wherein the conversion element has a bearing surface which is equal to or smaller than the cover surface of the semiconductor chip, and the bearing surface is completely in direct contact with the cover surface of the semiconductor chip,
wherein the conversion element has a cross-sectional area which tapers from the bearing surface towards the side of the conversion element facing away from the semiconductor chip, or wherein the conversion element has a cross-sectional area which tapers from a side of the conversion element facing away from the semiconductor chip towards the bearing surface, and/or
wherein the conversion element has side surfaces which have rounded corners.

2. The radiation-emitting component according to claim 1, wherein the bearing surface is equal to or smaller than the radiation exit surface.

3. The radiation-emitting component according to claim 1, wherein the semiconductor chip has side surfaces, and the side surfaces are free of the conversion element.

4. The radiation-emitting component according to claim 1, wherein the conversion element has side surfaces which have an average roughness of less than 2 μm and/or have no saw marks.

5. The radiation-emitting component according to claim 1, wherein the conversion element is applied only to partial regions of the semiconductor chip.

6. The radiation-emitting component according to claim 1, wherein an edge region of the cover surface of the semiconductor chip is free of the conversion element, wherein the edge region has a width selected from the range including 10 μm to including 12 μm.

7. The radiation-emitting component according to claim 1, one of the preceding claims, wherein the conversion element has a thickness which is less than or equal to 150 μm and/or which is greater than or equal to 10 μm.

8. The radiation-emitting component according to claim 1, wherein the conversion element has a solids content of greater than or equal to 45% by volume.

9. The radiation-emitting component according to claim 1, one of the preceding claims, wherein the matrix material has an organic content which is less than 40% by weight.

10. The radiation-emitting component according to claim 1, one of the preceding claims, wherein the matrix material has a Shore D hardness which is greater than 50.

11. The radiation-emitting component according to claim 1, wherein the matrix material is a three-dimensionally crosslinked polyorganosiloxane.

12. The radiation-emitting component according to the claim 11, wherein the three-dimensionally crosslinked polyorganosiloxane is prepared from a precursor material comprising an alkoxy-functionalized polyorganosiloxane resin.

13. The radiation-emitting component according to claim 1, further comprising connections for electrical contacting, wherein the connections are present on the side of the semiconductor chip facing away from the radiation exit surface.

14. The radiation-emitting component according to claim 1, further comprising connections for electrical contacting, wherein the connections are present on the side of the semiconductor chip facing the radiation emitting surface.

15. The radiation-emitting component according to claim 1, further comprising connections for electrical contacting, wherein the connections are present on the side of the semiconductor chip facing away from the radiation exit surface and on the side of the semiconductor chip facing the radiation exit surface.

16. A method for producing a radiation-emitting component comprising:
providing at least one semiconductor chip which, during operation, is configured to emits electromagnetic radiation of a first wavelength range from a radiation exit surface,
depositing a precursor material, in which phosphor particles are embedded, which convert electromagnetic radiation of the first wavelength range into electromagnetic radiation of a second wavelength range, directly onto at least one region of a cover surface of the semiconductor chip comprising the radiation exit surface,
curing the precursor material to form a conversion element comprising a matrix material and the phosphor particles embedded therein, wherein the conversion element has a bearing surface which is equal to or smaller than the cover surface of the semiconductor chip, and the bearing surface is completely in direct contact with the cover surface of the semiconductor chip,
wherein the precursor material is structured during deposition and the conversion element has a cross-sectional area which tapers from the bearing surface in the direction of the side of the conversion element facing away from the semiconductor chip, or the conversion element has a cross-sectional area which tapers from a side of the conversion element facing away from the semiconductor chip in the direction of the bearing surface, and/or
wherein the conversion element has side surfaces which have rounded corners.

17. The method according to the claim 16, wherein the curing is carried out at a temperature which is less than or equal to 220° C.

18. The method according to claim 16, wherein providing at least one semiconductor chip comprises providing a plurality of semiconductor chips, wherein the method further comprises singulating and curing the plurality of semiconductor chips after the deposition and curing of the precursor material.

19. The method according to claim 16, wherein the thickness and shape of the conversion element is adjusted during the deposition and/or the curing of the precursor material.

20. The method according to claim 16, wherein during curing the precursor material crosslinks three-dimensionally.
